(19) United States
(12) Patent Application Publication
(10) Pub. No.: US 2013/0025204 A1
(43) Pub. Date: Jan. 31, 2013

(54) DEVICE CONFIGURED FOR HANGING, SUPPORTING, AND GRIPPING

(71) Applicant: Wen-Hung Huang, New Taipei City (TW)

(72) Inventor: Wen-Hung Huang, New Taipei City (TW)

(73) Assignee: Hannspree, Inc., New Taipei City (TW)

(21) Appl. No.: 13/278,524

(22) Filed: Oct. 21, 2011

(30) Foreign Application Priority Data
Jul. 25, 2011 (TW) 100126135

(51) Int. Cl. H05K 7/00; F16M 13/00; E06B 7/28

(52) U.S. Cl. 49/70

(57) ABSTRACT

The present invention is to provide a device configured for hanging, supporting and gripping, which includes a supporting element and a cover. The supporting element is a strip-like plate made of a flexible material and provided with at least two fasteners on one side proximate to the ends thereof and each including a stem and a fastener cap, wherein the stem is connected to the plate at one end and is connected to the fastener cap at the other end. The cover is formed with an assembly hole and a track groove in communication with the assembly hole, wherein the assembly hole is sized and shaped to allow passage of each fastener cap, and the track groove is not sized and shaped to allow passage of the fastener caps, thereby the supporting element can be fastened to the cover through the fasteners for hanging, supporting and gripping the cover accordingly.

### FIELD OF THE INVENTION

The present invention relates to a device configured for hanging, supporting and gripping, more particularly to a portable device including a cover and a supporting element capable of being fastened to the cover as a whole, wherein the flexible body of the supporting element is deformable and adjustable for hanging, supporting and gripping the cover so that the cover can be hung on a wall, placed at different viewing angles or held by the user's hand, without other auxiliary devices.

### BACKGROUND OF THE INVENTION

Recently, with incessant improvement in microcomputer and material technologies, it has been a major goal in the electronic device industry to develop increasingly thinner and lighter products. At the same time, more and more people have changed their reading or photo viewing habits and converted from the conventional paper-based books or the traditional picture frames to e-book readers or digital frames as the principal media for accessing information. Aside from e-book readers, and thanks to the rapid development of mobile broadband network connection technology, a great variety of portable electronic devices—such as personal digital assistants (PDAs), smart phones, and tablet PCs—have played progressively important roles in people's daily lives and, for some, have even become indispensable tools for work, social networking, and learning. To enhance portability and adapt to people's viewing habits, these portable electronic devices are typically designed using flat panels, and in keeping with the goal of being compact and streamlined, they generally do not come with supporting or fixing accessories. Therefore, a user wishing to view the contents displayed by such a portable electronic device is required to grip the electronic device in one or both hands and adjust the viewing angle of the portable electronic device manually, which is highly undesirable. This holding posture is especially inconvenient for input operations, such as those to be performed on a tablet PC. While some of the aforementioned portable electronic devices are equipped with supporting elements, these supporting elements are good only for supporting the portable electronic devices in fixed positions. If it is desired to grip the portable electronic devices by hand while viewing images or inputting data, the supporting elements do not provide the required flexibility and convenience.

As a solution, structures similar to book holders were invented for supporting the aforesaid electronic devices. Like the supporting elements of a digital frame, however, these structures are suitable for use at fixed positions only and still fail to provide the desired flexibility and convenience. In particular, a user trying to operate an aforesaid portable electronic device during commute must grip the portable electronic device firmly in one hand to prevent it from dropping by accident, and yet gripping single-handed not only is physically demanding but also may hinder the operation of the other hand. With a view to allowing more flexible operation of the foregoing portable electronic devices, U.S. Pat. No. 6,726,070 discloses an input-device holder as shown in FIG. 1. The main body of the input-device holder consists of a board 1 and a plurality of supports 2 and 3 provided around the top side of the board 1 so that an input device 17 can be received between the supports 2 and 3. On the bottom side of the board 1 are a handle 5, two wrist supports 6, and a strap connection 7, wherein the handle 5 is configured to be gripped by the user, and the wrist supports 6 are connectable by the strap connection 7. The user's non-preferred hand is strapped between the two wrist supports 6, which are then connected by the strap connection 7. Once the handle 5 is gripped by the user's non-preferred hand, the input-device holder is securely attached to the user's non-preferred hand, allowing the user to operate the input device 17 in the input-device holder with the preferred hand. Nevertheless, the input-device holder still has its drawbacks. First of all, the input-device holder is too complicated in structure; this not only is reflected by its production, transportation, and storage costs, but also makes it difficult for the user to store or carry the input-device holder. Secondly, no matter the input-device holder is used with an input device or the aforementioned electronic devices, it must be a burden on the user's non-preferred hand when used for an extended period of time. Last but not least, although the input-device holder advantageously allows flexible operation, it is of no help when the user decides to place the input device on a fixed object for use. In fact, the input device cannot be so placed unless it is removed from the input-device holder, and it is very inconvenient having to attach/detach the input-device holder to/from the input device repeatedly.

Hence, despite the fact that it is generally desired to use the foregoing electronic devices under different conditions, so far there are no simple and practical solutions that are simultaneously applicable to the various conditions. As a result, one must use different devices to suit different needs, thus incurring high costs and great inconvenience. Therefore, the issue to be addressed by the present invention is to provide a simple and practical device that allows the aforesaid electronic devices to be conveniently used in different situations.

### BRIEF SUMMARY OF THE INVENTION

In view of the shortcomings particularly the lack of universal applicability to different situations of the conventional auxiliary supporting and gripping devices designed for use with portable electronic devices, the inventor of the present invention made extensive observation and research, and with inspiration from the body shape and movement of inchworms, the caterpillars of geometer moths, finally succeeded in developing a device configured for hanging, supporting, and gripping. It is hoped that this simple device will make it possible to use all kinds of electronic devices with ease in different situations.

The primary object of the present invention is to provide a device configured for hanging, supporting, and gripping, wherein the device includes a supporting element and a cover (e.g., the back cover of a portable electronic device, or a protective cover for protecting the back cover of the portable electronic device). The supporting element is a strip-like plate made of a flexible material (e.g., rubber) and provided with at least two fasteners on one side. The fasteners are proximate to the ends of the plate and each include a stem and a fastener cap, wherein the stem is connected to the plate at one end and is connected to the fastener cap at the other end. The cover is formed with a first assembly hole and a track groove in communication with the first assembly hole. The first assembly hole is sized and shaped to allow passage of each fastener cap. The track groove is not sized and shaped to allow passage of the fastener caps but corresponds in size and shape to the cross-section of each stem so that, after the fastener caps are sequentially inserted through the cover via the first assembly hole, the fasteners are movable along the track groove due to the matching size and shape of the stems and the track groove. Once the fasteners are moved away from the first assembly hole along the track groove, the fastener caps can be respectively and engagingly secured at least two different positions of the cover, thereby fastening the supporting element to the cover. As long as the supporting element is assembled to the cover, the cover can be hung, held, or supported by way of the plate. Also, the supporting element can be easily detached from the cover for storage. Moreover, when the fasteners provided at different positions of the supporting element are moved along the track groove, variation of the relative positions of the fasteners results in corresponding deformation of the plate. The user can adjust the curvature of deformation of the plate so that, when the cover and the electronic device connected thereto are to be hung, supported, or held, adjustment can be made to the hanging angle, the supporting height, and the tightness of grip.

It is another object of the present invention to provide the foregoing device configured for hanging, supporting, and gripping, wherein the track groove has a wavy shape for increasing the friction between the track groove and the stems fitted therein. The wavy shape also prevents the interaction between forces applied by the user to the plate during use and the resilient restoring force of the plate itself from shifting the fasteners away from the positions set by the user.

It is yet another object of the present invention to provide another device configured for hanging, supporting, and gripping, wherein the device includes a supporting element and a cover. The supporting element is made of a flexible material and formed as a strip-like plate. The plate is provided with at least two fasteners which are located adjacent to the ends of the plate. Each fastener includes a stem, a positioning portion, and a fastener cap, wherein the stem has a first end connected to the plate and a second end connected to a first end of the positioning portion, and the positioning portion has a second end connected to one end of the fastener cap. The cover is formed with a first assembly hole, a plurality of positioning holes, and a plurality of track grooves. The first assembly hole and the adjacent positioning hole(s), as well as each two adjacent positioning holes, are connected by the track grooves. The first assembly hole is sized and shaped to allow passage of each fastener cap. The track grooves are not sized and shaped to allow passage of the fastener caps or the positioning portions but correspond in size and shape to the cross-section of each stem. The positioning portions correspond in size and shape to the positioning holes. Thus, after the fastener caps are sequentially inserted through the cover via the first assembly hole, the matching sizes and shapes of the stems and the track grooves allow the fasteners to move along the track grooves. Once the fasteners are moved away from the first assembly hole along the track grooves, the positioning portions can be engaged and secured in the corresponding positioning holes respectively. As a result, the fasteners are respectively and engagingly fixed at least two different positions of the cover, and the supporting element is thereby fastened to the cover.

Still another object of the present invention is to provide the foregoing two devices, wherein the plate of each device is formed with at least one slit located farther away from the ends of the plate than the fasteners so as to facilitate bending of the plate.

According to the above, while the supporting element is being fastened to the back cover of a panel-shaped electronic device via the fasteners, the supporting element is adjustable so that the electronic device can be hung or placed at different angles or held by user's hand, without having to change any auxiliary devices. Besides, the supporting element is easily detachable, and the detached supporting element can be conveniently stored and carried. It is also feasible to produce a protective cover for an electronic device and provide the protective cover with the aforesaid assembly hole and track grooves so that, once the protective cover is connected to the electronic device, the foregoing device configured for hanging, supporting, and gripping can be used in the same way as described above. Therefore, in addition to its structural simplicity, the prevent invention features wide applicability to various devices and situations.

### BRIEF DESCRIPTION OF THE SEVERAL VIEWS OF THE DRAWINGS

The structure as well as a preferred mode of use, further objects, and advantages of the present invention will be best understood by referring to the following detailed description of some illustrative embodiments in conjunction with the accompanying drawings, in which:

FIG. 1 is a perspective view of a conventional input-device holder in use;

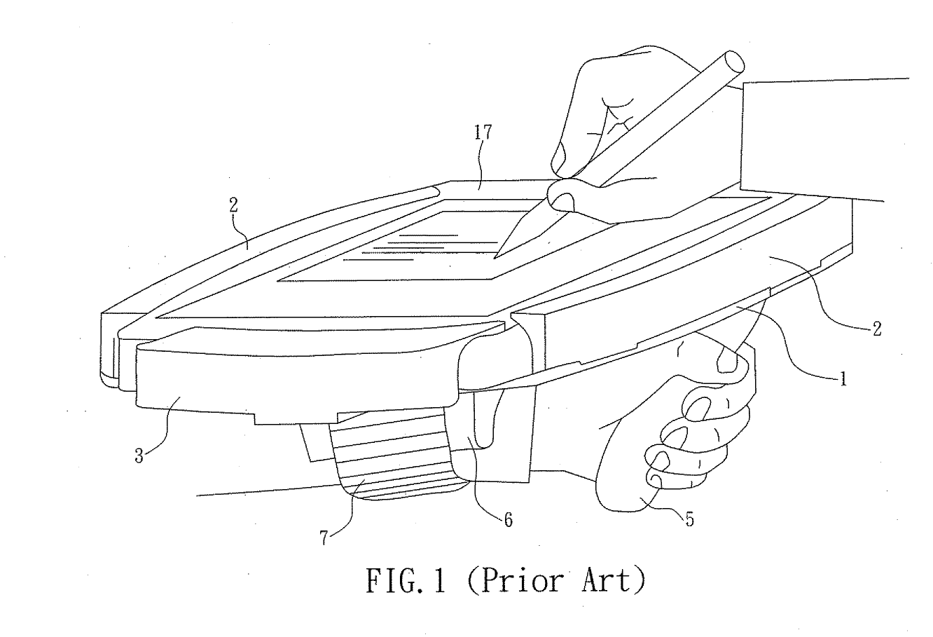

FIG. 2 is an exploded perspective view of the first preferred embodiment of the present invention;

FIG. 3 illustrates the sequence of the assembly steps of the first preferred embodiment of the present invention;

FIG. 4 is an enlarged view of the end structure of a supporting element in the first preferred embodiment of the present invention;

FIG. 5 is an exploded perspective view of the second preferred embodiment of the present invention;

FIG. 6 is a perspective view of the second preferred embodiment of the present invention;

FIG. 7 is an enlarged view of the end structure of a supporting element in the second preferred embodiment of the present invention; and

FIG. 8 shows the second preferred embodiment of the present invention in use.

### DETAILED DESCRIPTION OF THE INVENTION

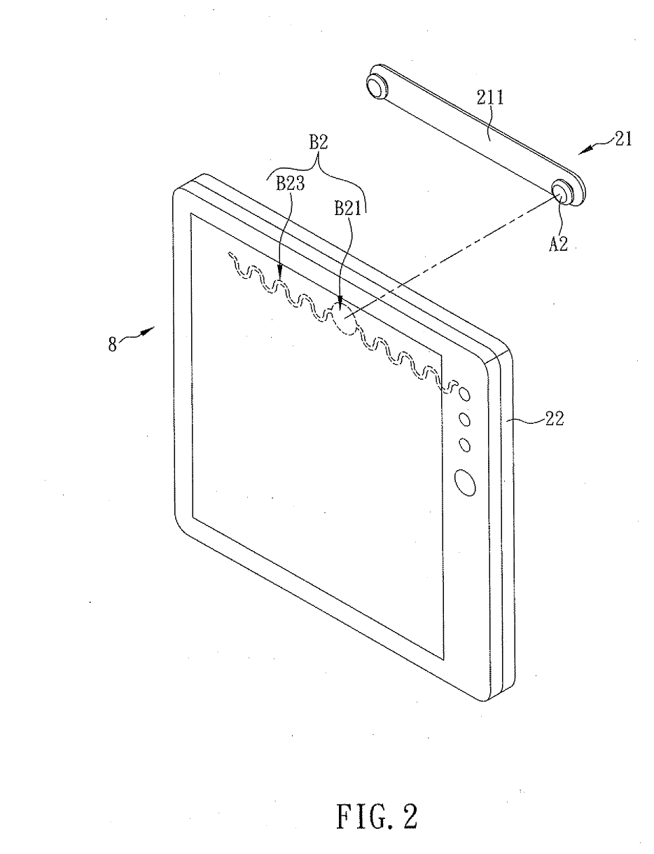

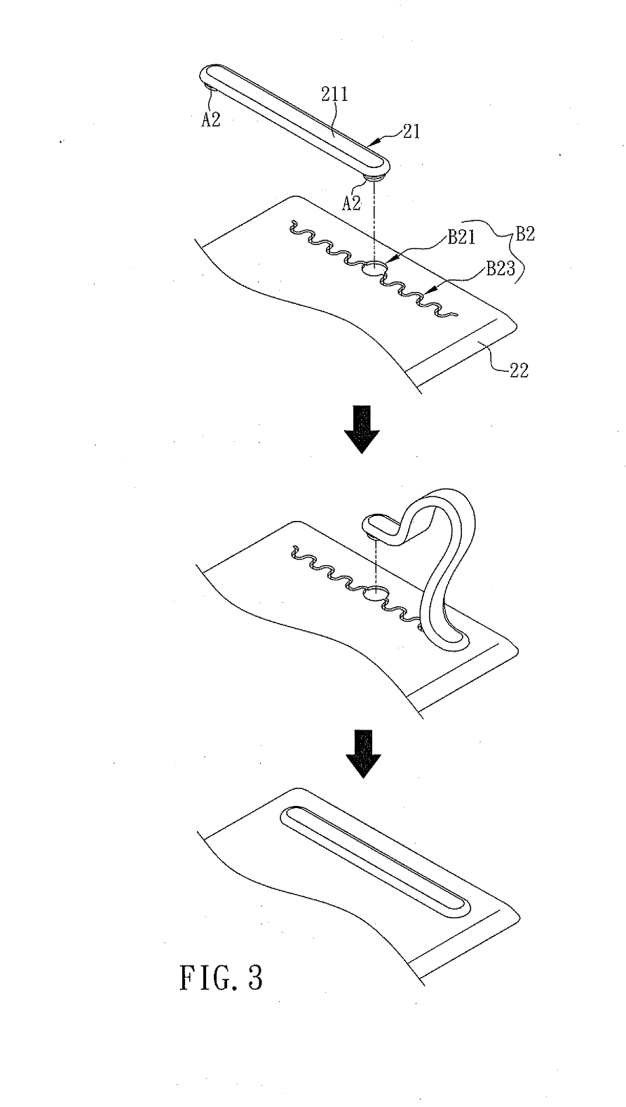

The present invention provides a device configured for hanging, supporting, and gripping. The device is applicable mainly to a portable electronic device 8 (e.g., a tablet PC) and serves as an auxiliary tool. Referring to FIGS. 2 and 3 for the first preferred embodiment of the present invention, the device includes a supporting element 21 and a cover 22. The supporting element 21 is made of a flexible material (e.g., rubber, silicone, etc.) and formed as a strip-like plate 211. In the first embodiment, the plate 211 is a strip-like rectangular plate with rounded corners, and yet the shape of the plate 211 is not limited thereto. For example, the plate 211 can be isosceles triangular, elliptical, bat-shaped, saury-shaped, or of any other planar or three-dimensional shapes. In short, the shape of the plate 211 can be designed according to actual esthetic requirements.

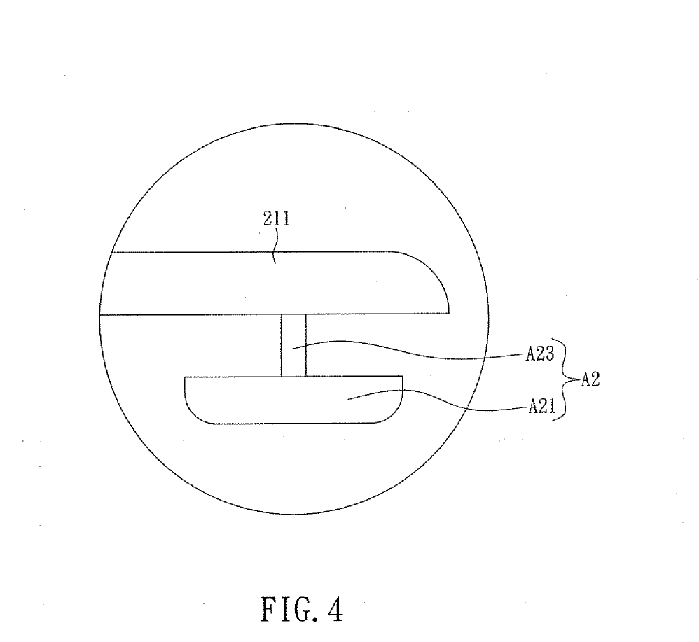

The plate 211 is provided with two fasteners A2 on one same surface. The fasteners A2 are located adjacent to the two opposite ends of the plate 211 respectively. As shown more clearly in FIG. 4, each fastener A2 includes a stem A23 and a fastener cap A21, wherein the stem A23 is connected to the plate 211 at one end and is connected to the fastener cap A21 at the other end. In the first embodiment, referring to FIG. 2, the cover 22 is the back cover of the portable electronic device 8 and has a first assembly hole B21 and two track grooves B23. The first assembly hole B21 communicates with each track groove B23 so as to form a channel B2 in which the first assembly hole B21 is located away from both ends of the channel B2. The first assembly hole B21 is sized and shaped to allow passage of each fastener cap A21 (shown in FIG. 4).

As shown in FIGS. 3 and 4, the fastener caps A21 depicted in the drawings of each embodiment in this specification have a circular coin-shaped structure. Meanwhile, the first assembly hole B21 is a circular hole corresponding in size and shape to the fastener caps A21. However, the structure of the fastener caps A21 is not limited to that disclosed herein. Not only is it feasible to change the shapes of the fastener caps A21 and the first assembly hole B21, but also the fastener caps A21 and the first assembly hole B21 do not necessarily match each other. For instance, the first assembly hole B21 can be a generally semicircular hole through which the fastener caps A21 cannot pass unless the fastener caps A21 are tilted beyond a certain angle. Hence, the first assembly hole B21 in the present invention can be any hole whose size and shape allow the fastener caps A21 to pass through the hole. The phrases “allow passage” and “do not allow passage” and their equivalents are used herein to describe the relationship between components, where applicable.

The track grooves B23 are not sized and shaped to allow passage of the fastener caps A21; however, the track grooves B23 correspond in size and shape to the cross-section of each stem A23. Once sequentially inserted through the cover 22 via the first assembly hole B21, the fastener caps A21 can be moved away from the first assembly hole B21 along the track grooves B23 respectively, before the fasteners A2 are engagingly secured in the respective track grooves B23 of the cover 22 and thereby fasten the plate 211 to the cover 22. The track grooves B23 in this embodiment have a wavy shape. In addition to increasing the friction between the track grooves B23 and the stems A23 fitted therein, the wavy track grooves B23 prevent the fasteners A2 from being driven away from the user's intended positions by any external force applied to the plate 211 during use or by the resilient restoring force of the plate 211 itself. Nonetheless, the shape of the track grooves B23 is not limited to the foregoing.

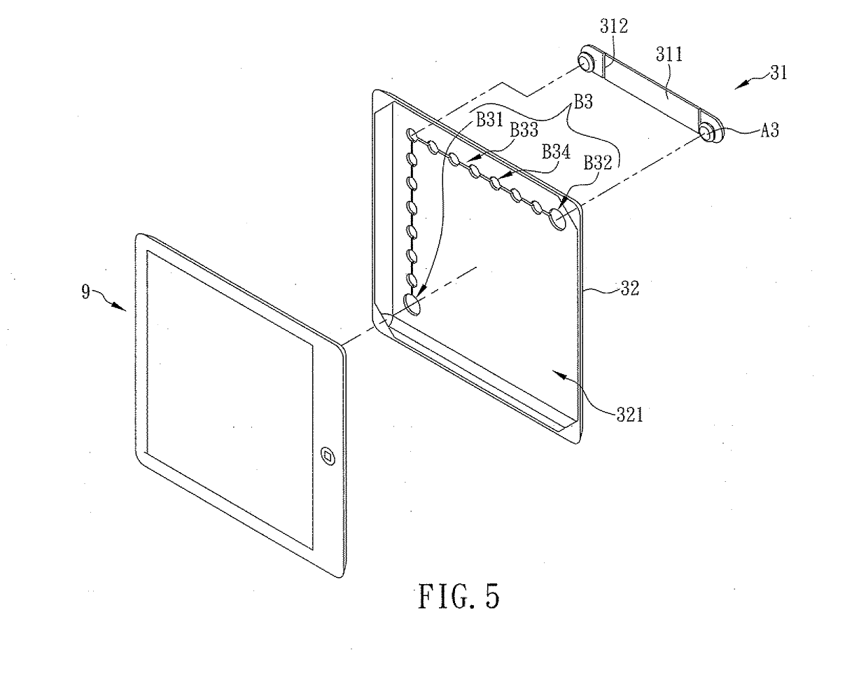

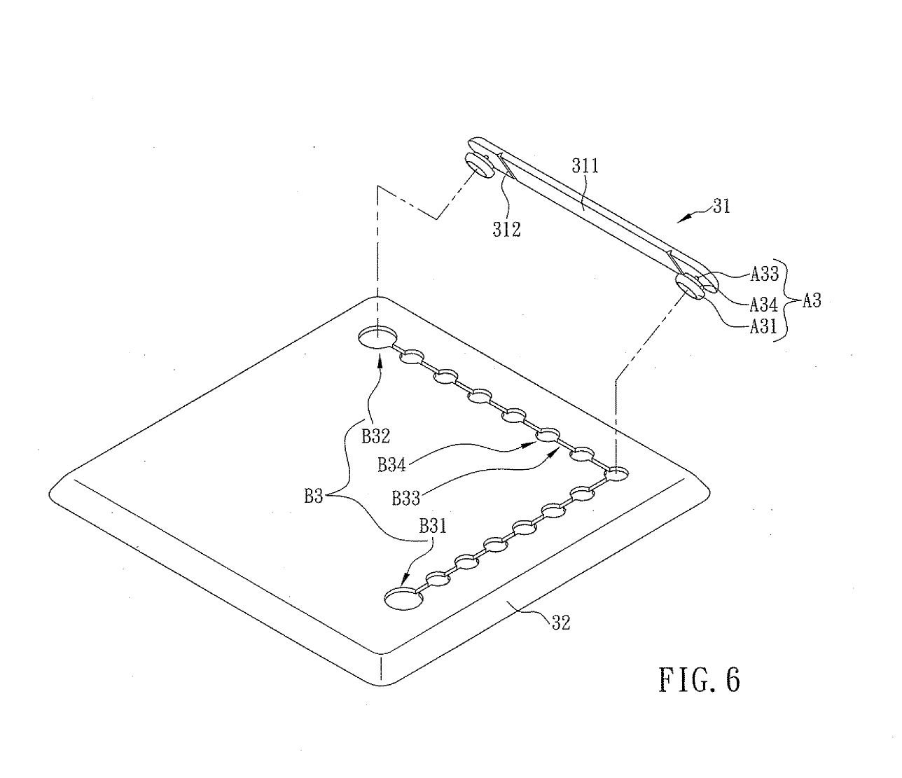

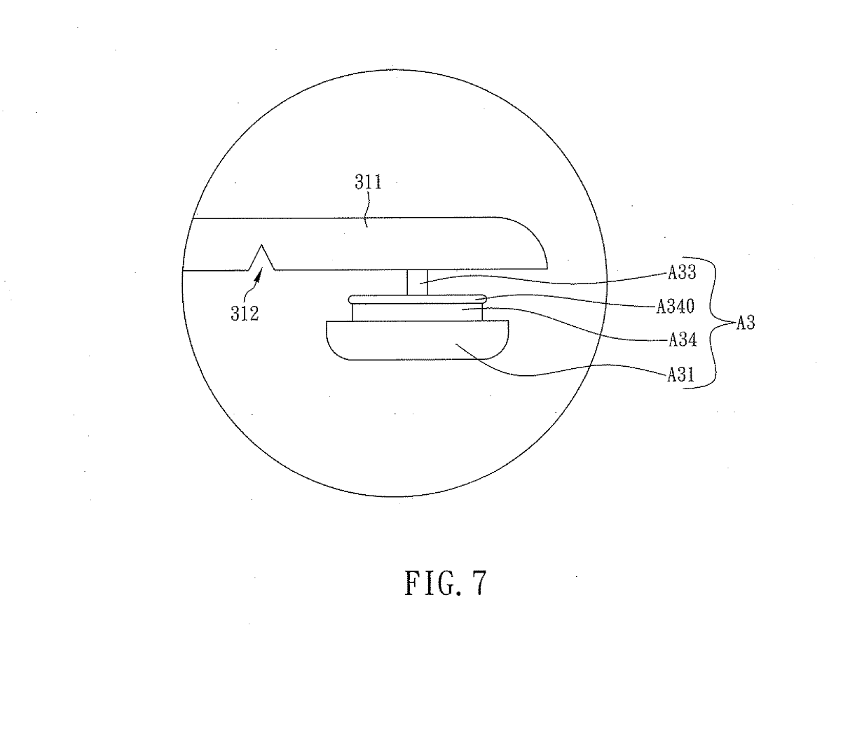

Referring to FIGS. 5 and 6, a device according to the second preferred embodiment of the present invention includes a supporting element 31 and a cover 32. The supporting element 31 consists of a strip-like plate 311 and two fasteners A3, wherein the fasteners A3 are located adjacent to the two opposite ends of the plate 311 respectively. As shown more clearly in FIG. 7, each fastener A3 includes a stem A33, a positioning portion A34, and a fastener cap A31. The stem A33 has a first end connected to the plate 311 and a second end connected to a first end of the positioning portion A34, while a second end of the positioning portion A34 is connected to the fastener cap A31. Besides, in order to facilitate bending of the plate 311, two slits 312 are formed on the plate 311 at positions farther away from the two opposite ends of the plate 311 than the fasteners A3.

In the second preferred embodiment, referring to FIG. 5, the cover 32 is a protective cover for a portable electronic device 9 and defines a receiving space 321 for receiving the portable electronic device 9. The cover 32 is formed with a first assembly hole B31, a second assembly hole B32, a plurality of track grooves B33, and a plurality of positioning holes B34. By virtue of the track grooves B33, the first assembly hole B31 communicates with the adjacent positioning hole B34, each two adjacent positioning holes B34 communicate with each other, and the second assembly hole B32 communicates with the adjacent positioning hole B34; thus, a channel B3 is formed. The first assembly hole B31 is located at one end of the channel B3, and the second assembly hole B32 is at the other end of the channel B3. The first assembly hole B31 and the second assembly hole B32 are sized and shaped to allow passage of each fastener cap A31 (see FIG. 7).

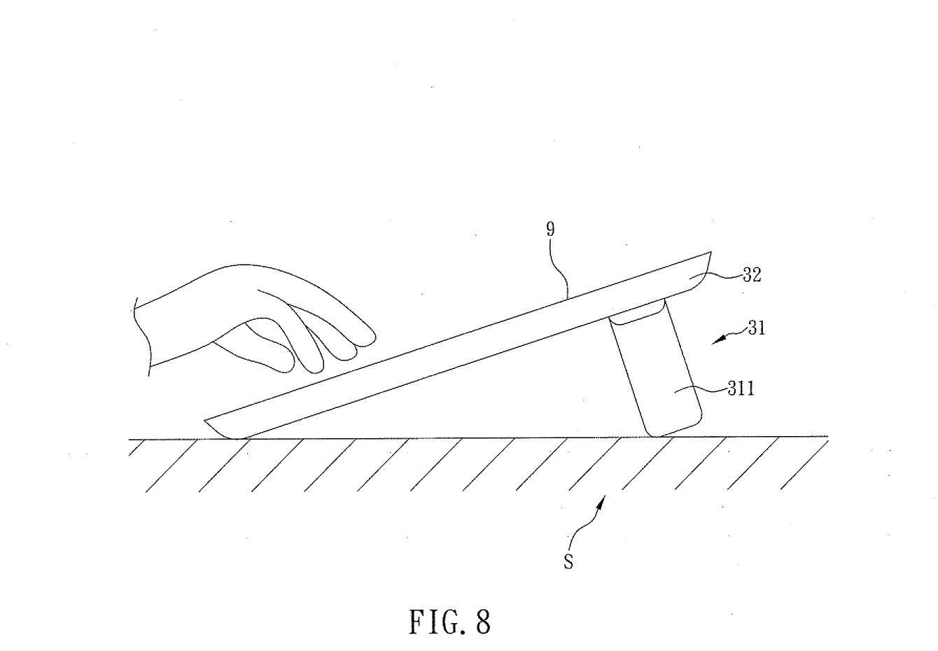

With reference to FIGS. 6 and 7, the track grooves B33 are not sized and shaped to allow passage of the fastener caps A31 or the positioning portions A34 but correspond in size and shape to the cross-section of each stem A33. After the fastener caps A31 are inserted through the cover 32 via the first assembly holes B31 and the second assembly hole B32 respectively, the fasteners A3, whose sterns A33 correspond in size and shape to the track grooves B33, and can be moved along the track grooves B33. Once the fasteners A3 are moved away from the first assembly hole B31 and the second assembly hole B32 along the track grooves B33, the fastener caps A31 can be respectively and engagingly secured at different positions of the cover 32 to fasten the plate 311 to the cover 32, thus allowing the portable electronic device 9 to be hung on a wall-mounted hook via the plate 311. The user may also grip the plate 311 with the non-preferred hand or pass the non-preferred hand through the space between the plate 311 and the cover 32; in either case, the portable electronic device 9 is securely positioned on the user's non-preferred hand and can be operated by the user's preferred hand. Moreover, referring to FIG. 8, it is feasible to place the portable electronic device 9 on a fixed surface S, with the cover 32 supported by the plate 311 on one side, thus tilting the portable electronic device 9 toward the user for ease of operation. Apart from that, the supporting element 31 (see FIG. 6) can be easily detached from the cover 32 so as to be put away.

As shown in FIGS. 6 and 7, when the fasteners A3 are moved along the channel B3, the relative positions of the fasteners A3 are changed, and the plate 311 is deformed accordingly. Hence, the user can adjust the curvature of deformation of the supporting element 31 to suit practical needs. For example, by moving the fasteners A3 along the channel B3, adjustment can be made to the angle between the portable electronic device and the wall on which it is hung, the tightness with which the portable electronic device is connected to the user's non-preferred hand, or the tilting viewing angle at which the portable electronic device is placed on a fixed surface S. The positioning portions A34, although not sized and shaped to pass through the track grooves B33, correspond in size and shape to the positioning holes B34. The positioning holes B34, on the other hand, are not sized and shaped to allow passage of the fastener caps A31. Therefore, it is the positioning portions A34 of the fasteners A3 that can be positioned in the positioning holes B34. The positioning portions A34, which match the positioning holes B34, are effective in securely positioning the fasteners A3, so forces applied to the plate 311 during use and the resilient restoring force of the plate 311 itself are prevented from moving the fasteners A3 away from the positions set by the user.

To further increase the stability with which the positioning portions A34 can be engaged in the positioning holes B34, the end of each positioning portion A34 that is adjacent to the corresponding stem A33 is provided with a lug A340. Once the positioning portions A34 are connected to the positioning holes B34, the lugs A340 can prevent the positioning portions A34 from falling off.

While the cover 32 in the second embodiment is formed with the first assembly hole B31, the second assembly hole B32, the track grooves B33, and the positioning holes B34, the structure of the cover 32 is not limited to the foregoing. The number of the assembly holes can be increased or decreased as appropriate. For example, the second assembly hole B32 in the second embodiment can be omitted while the first assembly hole B31 remains. In that case, the fastener caps A31 are sequentially inserted through the cover 32 by way of the first assembly hole B31, and then the fasteners A3 can be moved along the track grooves B33 due to the correspondence in size and shape between the stems A33 and the track grooves B33. Furthermore, instead of being provided at the ends of the channel B3 respectively, the first assembly hole B31 and the second assembly hole B32 can be located between any two adjacent positioning holes B34 and communicate with the positioning holes B34 through the track grooves B33. By the same token, it is feasible to modify the structure of the cover 22 in the first embodiment. For example, the first assembly hole B21 can be located at one end of the channel B2, or the cover 22 can be provided with a plurality of assembly holes as in the second embodiment. All equivalent changes easily conceivable by a person skilled in the art should fall within the scope of the present invention.

Referring to FIG. 5 and FIG. 6, as many portable electronic devices are designed for operation in both vertical and horizontal positions, the channel B3 can be provided along two adjacent sides of the cover 32 and hence take an L shape. This allows the user to connect the supporting element 31 to different sides of the cover 32 as needed. Further, referring to FIGS. 2 and 5, the distance between the two fasteners A2 is preferably shorter than the length of the channel B2, and the distance between the two fasteners A3 is preferably shorter than the length of the channel B3, so as to prevent the fasteners A2 from easily escaping the first assembly hole B21 in the channel B2, and the fasteners A3 from easily escaping the first assembly hole B31 and the second assembly hole B32 in the channel B3. These relatively short distances between the fasteners A2 and between the fasteners A3 also ensure that the fasteners A2 and A3 can be positioned in the channels B2 and B3 respectively.

While the invention herein disclosed has been described by means of specific embodiments, numerous modifications and variations could be made thereto by those skilled in the art without departing from the scope and spirit of the invention set forth in the claims.

What is claimed is:

1. A device configured for hanging, supporting, and gripping, the device comprising:
a supporting element made of a flexible material and formed as a strip-like plate, the plate being provided with at least two fasteners located adjacent to two ends of the plate, each said fastener comprising a stem and a fastener cap, wherein the stem has an end connected to the plate and an opposite end connected to the fastener cap; and
a cover formed with a first assembly hole and at least a track groove, the first assembly hole communicating with the track groove and being sized and shaped to allow passage of said fastener cap, each said track groove corresponding in size and shape to a cross-section of each said stem but not allowing passage of the fastener cap, wherein after the fastener caps are sequentially inserted through the cover via the first assembly hole, the fasteners are movable along the track groove due to correspondence in size and shape between the stems and the track groove, and once the fasteners are moved away from the first assembly hole along the track groove, the fastener caps can be respectively and engagingly fixed at least two different positions of the cover, thereby fastening the supporting element to the cover.

2. The device of claim 1, wherein the first assembly hole and the track groove in communication therewith jointly form a channel, and the first assembly hole is located at an end of the channel.

3. The device of claim 1, wherein the cover is further formed with a second assembly hole, and the first assembly hole, the second assembly hole, and the track groove communicate with each other and jointly form a channel, the first assembly hole and the second assembly hole being located at opposite ends of the channel respectively, the fastener caps being allowed to pass through the cover via the first assembly hole and the second assembly hole respectively.

4. The device of claim 1, wherein the first assembly hole and the track groove in communication therewith jointly form a channel, and the first assembly hole is located away from two opposite ends of the channel.

5. The device of claim 1, wherein each said fastener further comprises a positioning portion provided between the stem and the fastener cap of the each said fastener and having an end connected to the stem and an opposite end connected to the fastener cap, and the cover further comprises a plurality of positioning holes corresponding in size and shape to the positioning portions and communicating with the first assembly hole via the track groove so that, once the fastener caps are sequentially inserted through the cover via the first assembly hole, the positioning portions can be engaged and fixed in corresponding said positioning holes, allowing the fasteners to be respectively and engagingly fixed at the at least two different positions of the cover, thereby fastening the supporting element to the cover.

6. The device of claim 1, wherein the cover is a back cover fixedly connected to a portable electronic device.

7. The device of claim 1, wherein the cover is a protective cover selectively connectable to a portable electronic device.

8. The device of claim 2, wherein a distance between two outermost said fasteners is shorter than a length of the channel.

9. The device of claim 3, wherein a distance between two outermost said fasteners is shorter than a length of the channel.

10. The device of claim 4, wherein a distance between two outermost said fasteners is shorter than a length of the channel.

11. The device of claim 5, wherein each said positioning portion comprises a lug.

12. The device of claim 8, wherein the track groove has a wavy shape.

13. The device of claim 9, wherein the track groove has a wavy shape.

14. The device of claim 10, wherein the track groove has a wavy shape.
